(19) United States
(12) Patent Application Publication
(10) Pub. No.: US 2014/0132312 A1
(43) Pub. Date: May 15, 2014

(54) EFFICIENCY OPTIMIZED DRIVER CIRCUIT

(71) Applicant: Fairchild Semiconductor Corporation, San Jose, CA (US)

(72) Inventor: Laszlo Balogh, Merrimack, NH (US)

(73) Assignee: Fairchild Semiconductor Corporation, San Jose, CA (US)

(21) Appl. No.: 14/081,442

(22) Filed: Nov. 15, 2013

Related U.S. Application Data
(60) Provisional application No. 61/726,710, filed on Nov. 15, 2012.

(51) Int. Cl. H03K 17/06

(52) U.S. Cl. CPC H03K 17/06
USPC 327/109; 323/312

(57) ABSTRACT

Driver circuitry and methods are provided for driving a semiconductor device. The driver circuitry includes a buck converter configured to generate a baseline current, and a capacitor coupled between an output of the buck converter and ground, the capacitor configured to store charge during an off-state of the buck converter and to discharge the stored charge as a peak current during an on-state of the buck converter, wherein the baseline current reaches a current limit prior to the capacitor being fully discharged, and an output current at an output of the buck converter is based, at least in part, on the baseline current and the peak current.

### CROSS-REFERENCE TO RELATED APPLICATIONS

The present application claims the benefit of U.S. provisional application Ser. No. 61/726,710, filed Nov. 15, 2012, which is incorporated fully herein by reference.

### FIELD

The present disclosure relates to driver circuitry, and, more particularly, to a driver circuit for efficiently generating base current for current driven type semiconductor devices requiring constant current drive during an on-state.

### BACKGROUND

A transistor is a semiconductor device generally used in electronic devices to amplify and/or switch electronic signals and electrical power. Transistors are composed of semiconductor material with at least three terminals for connection to an external circuit, wherein a voltage or current applied to one pair of the transistor's terminals changes the current flowing through another pair of terminals.

A bipolar junction transistor (BJT), for example, is a type of well-known transistor that generally includes at least three terminals, a base, an emitter, and a collector. Generally, to turn a BJT to an on-state, current is applied to the base terminal. Some current systems may include a driver (hereinafter referred to as “driver circuit”) for controlling and driving the BJT. Driver circuits may be used to regulate current flowing through a circuit and/or or to control other factors or components in the circuit. A driver circuit may include a circuit input configured to be driven to a predefined positive voltage level by a voltage source and further configured to apply current through a resistor coupled to the base terminal of the BJT. The BJT will then conduct a current from its collector terminal to its emitter terminal of up to a ratio Beta (β) times the current flowing from the base terminal to the emitter terminal. Beta is a device- and operating-condition-dependent parameter subject to process variations; typically circuits are designed to operate with devices having a range of Beta ratios to ease manufacture.

Current systems and methods for driving transistors, particularly BJTs, have drawbacks. For example, in a driver circuit system as described above, applying a voltage and setting the base current by a resistor in order to drive the BJT results in dissipation of power. Additionally, during operation, a space charge builds up in the base-emitter junction of the BJT, and to turn the BJT off (i.e. transition to an off-state), the space charge must be dissipated. As such, current systems and methods generally require dissipation, which results in power loss, leading to inefficient power maintenance.

### BRIEF DESCRIPTION OF DRAWINGS

Features and advantages of the claimed subject matter will be apparent from the following detailed description of embodiments consistent therewith, which description should be considered with reference to the accompanying drawings, wherein:

FIG. 1 illustrates an example embodiment of driver circuitry consistent with the present disclosure;

FIG. 2 illustrates another example embodiment of driver circuitry consistent with the present disclosure;

FIG. 3 illustrates one example embodiment of driver circuitry consistent with the present disclosure;

FIG. 4 illustrates one example embodiment of driver circuitry consistent with the present disclosure;

FIG. 5 is a flowchart of operations according to some example embodiments; and

FIG. 6 illustrates a waveform diagram according to some example embodiments.

Although the following Detailed Description will proceed with reference being made to illustrative embodiments, many alternatives, modifications, and variations thereof will be apparent to those skilled in the art.

### DETAILED DESCRIPTION

By way of overview, the present disclosure is directed to a system for efficiently driving transistors. In particular, the system includes a current-controlled switching device, such as a bipolar junction transistor (BJT), for driving a load and a driver circuit coupled to the BJT and configured to efficiently drive the BJT. The BJT may require constant current driving during an on-state. The driver circuit includes a buck converter configuration for efficiently generating base current for driving a base terminal region of the BJT. The buck converter configuration of the driver circuit is configured to provide a more efficient method of generating the base current needed for the BJT to operate.

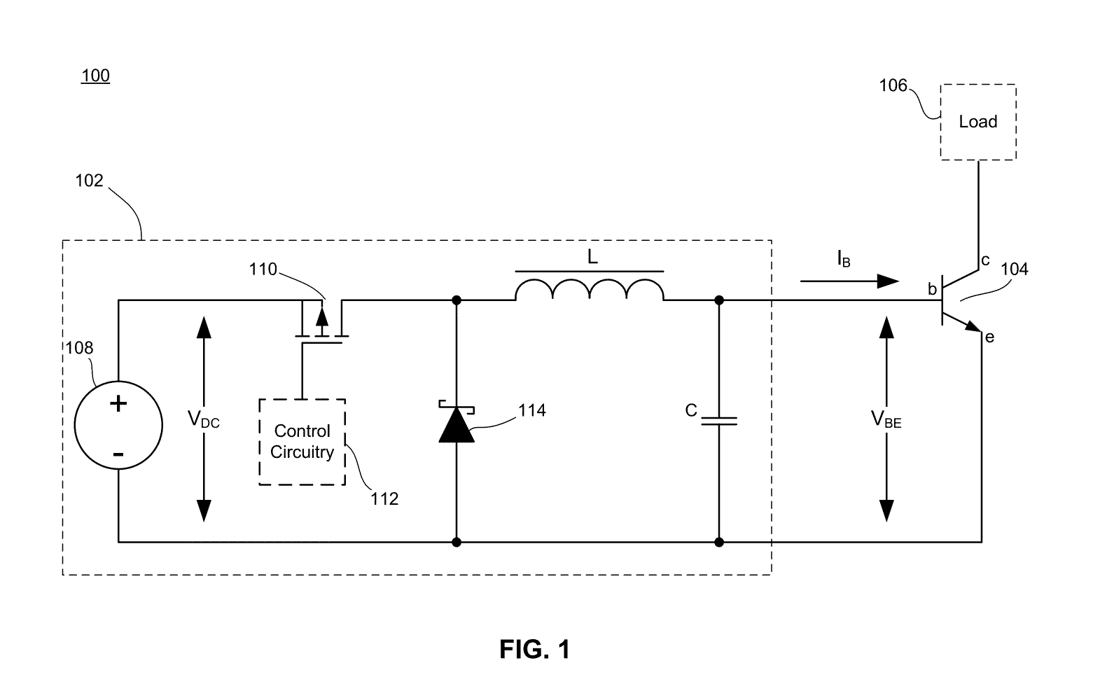

FIG. 1 illustrates a system 100 for driving a transistor consistent with the present disclosure. The system 100 depicted in FIG. 1 may be included with, or form part of, a general-purpose or custom integrated circuit (IC) such as a semiconductor integrated circuit chip, system on chip (SoC), etc. The system 100 may include driver circuitry 102 configured to generate and apply current to a BJT 104 for driving a load 106. The BJT 104 may include three differently doped semiconductor regions: an emitter region, a base region and a collector region. As shown, the BJT 104 is an NPN configuration and these regions are, respectively, n type, p type and n type, wherein each semiconductor region is connected to a terminal, appropriately labeled: emitter (e), base (b) and collector (c).

As shown, the driver circuitry 102 includes a buck converter configuration for generating and applying base current I_{B} to the base terminal b of the BJT 104. The base current I_{B} is then amplified to produce a large collector and emitter current. For example, when there is a positive potential difference measured from the emitter e to the base b (i.e., when the base b is high relative to the emitter e), the BJT 104 is forward-active (or simply, “active”) or in saturation. If the voltage at the collector terminal is greater than the voltage at the base terminal, the BJT 104 is in active mode. If the voltage at the base terminal is greater than the voltage at the collector terminal, the BJT 104 is in saturation, which corresponds to a logical “on-state” or a closed switch. In the on-state, current flows between the collector c and emitter e of the BJT 104.

Some current driven type semiconductor devices, such as, for example, the BJT 104, as well as some voltage driven type devices (e.g. junction gate field-effect transistors (JFETs)) may require a constant current drive during an on-state. The buck converter configuration of the driver circuitry 102 is configured to efficiently generate base current I_{B} for the BJT 104 that is continuous during operation of the driver circuitry 102. As shown, the BJT 104 has a base b coupled to an output of the driver circuitry 102. The driver circuitry 102 may include an inductor L and an output capacitor C. The inductor L may be coupled to a voltage source 108 by way of a switching device 110. As shown, the switching device 110 is a field-effect transistor (FET), more specifically a P-Channel single-gate enhancement mode FET. The switching device 110 may be controlled by control circuitry 112. As generally understood, the control circuitry 112 may be configured to control the switching device 110 between open and closed states. For example, if the switching device 110 is open, the voltage source 108 is removed from the circuit and disconnected from the inductor L, while if the switching device 110 is closed, the voltage source 108 is coupled to the inductor L. The control circuitry 112 may include pulse width modulation (PWM) circuitry, power switch driver circuitry, and power switch circuitry, including at least one power switch device (e.g., PMOS, NMOS, SiC, etc.).

The inductor L may be further coupled to a diode 114 to provide a path for the inductor current during the off-state of the switching device 110. As shown, the diode 114 may include a Schottky diode 114. It should be noted that the diode 114 may include any other known type of diode or synchronous rectifier solution, such as, for example, a metal-oxide-semiconductor FET (MOSFET) controlled in a complementary manner with respect to the switching device 110, configured for use with high frequency circuits and providing low voltage drops in the forward direction and fast switching action.

In some example embodiments, the BJT 104 may include Silicon Carbide (SiC) or may be a SiC device. SiC has advantageous material properties for semiconductor power devices, such as BJTs. For example, SiC has a high breakdown electric field that enables the fabrication of small, low-resistive and fast switching high-voltage, high-power devices. The breakdown field is about ten times higher than that of silicon. SiC also has thermal conductivity nearly three times higher than silicon. SiC devices are therefore able to operate at extremely high power levels whilst efficiently dissipating the generated excess heat. The wide band gap of SiC opens up for SiC devices to be used at very high temperatures, which is of great importance when performing, for example, down hole drilling or making compact low weight power electronics.

Due to the above mentioned qualities, transistors with SiC are electrically very robust. The ability to operate at high temperatures enables them to withstand short circuit operation or over load conditions for longer times. Power transistors made out of SiC have a positive temperature coefficient, which makes them free from the troublesome secondary breakdown and makes them easy to parallel. The high saturated electron drift velocity of SiC allows for SiC devices to operate at high frequencies, which is also beneficial for decreasing the size of passives.

If the BJT 104 includes SiC, the BJT 104 may have the following characteristics. The BJT 104 may have a wide bandgap, and thus the base emitter voltage V_{BE} of the BJT 104 may be ˜3V during conduction. The BJT 104 may have a base resistance R_{B} significantly lower than a gate resistance R_{G} generally found in MOSFETs. The BJT 104 may generally require a DC base current I_{B} during conduction. Finally, a BJT 104 including SiC may have “MOSFET-like” capacitances, C_{BE} and C_{BC}, which need to be charged quickly to achieve fast switching speed. Accordingly, the BJT 104 could be considered a charge-controlled device during the fast switching intervals (i.e. the switching performance of the device is determined how quickly charge can be moved in or out of the capacitances).

While FIGS. 1-4 illustrate the driver circuitry 102 driving a BJT 104, example embodiments may vary and are not limited thereto. For example, the driver circuitry 102 is configured to generate a high peak current and then a lower steady state current, which may be used to drive other devices in addition to SiC BJT's. Therefore, the driver circuitry 102 may be used to drive any device having a similar current profile to a SiC BJT, such as a high current thyristor or a SiC metal-oxide-semiconductor FET (MOSFET). While the operation of the high current thyristor or SiC MOSFET may vary from the operation disclosed for the SiC BJT, example embodiments may be configured to generate the required current.

Typical current driver circuit systems include a resistor connected to the base of the BJT. In contrast, example embodiments may include a buck converter configuration for the driver circuitry 102, which is more efficient than the resistor commonly used. Example embodiments are not limited thereto, however, and may include configurations other than the buck converter illustrated in FIG. 1. As the base current I_{B} (in current limit) generated by the driver circuitry 102 is independent from both the source voltage V_{AC} and the base-emitter voltage V_{BE}, the driver circuitry 102 may result in power savings as much as 75% (assuming 15V bias, an SiC BJT and 80% efficient buck conversion (power loss is ¼th)).

For example, a typical current driver circuit may generate a constant steady state base current for the BJT. As the base current I_{B} is a function of the maximum collector current that the BJT must carry, the typical drive circuit must generate the constant steady state base current based on the initial high peak current to enable the BJT to transition to the on-state.

In contrast, the driver circuitry 102 may be configured to provide the initial peak current for transitioning the BJT 104 to the on-state while also providing the steady state base current I_{B} during the on-state with increased efficiency. To provide the initial peak current, the driver circuitry 102 may store charge in the output capacitor C. At turn on of the BJT 104, the charge stored in the output capacitor C may be discharged into the base terminal b of the BJT 104 to provide the initial high peak current generally required for fast switching action.

To provide the steady state base current I_{B} with improved efficiency, the driver circuitry 102 may be configured to operate in a current limit setting during the on-state of the BJT 104. As the output capacitor C may provide the initial high peak current required by the BJT 104 for transitioning to the on-state, the driver circuitry 102 may operate in the current limit setting and generate a current based only on the steady state base current I_{B} required by the BJT 104 after the transition to the on-state. Therefore, the driver circuitry 102 may reduce the base current I_{B} from the maximum required by the BJT 104 for transitioning to the on-state to slightly more than a minimum steady state base current I_{B} required by the BJT 104 for operation. Thus, the positive turn-on voltage may become V_{BE}+I_{B}*R_{SW}, which is an optimum voltage to achieve ideal efficiency. Due to the high frequency operation of the buck converter configuration, the driver circuitry 102 will reach current limit by the time the output capacitor C is discharged, providing uninterrupted, continuous base current I_{B} during operation of the driver circuitry 102.

As the driver circuitry 102 may be configured to reduce the base current I_{B} during the conduction period of the BJT 104, the driver circuitry 102 may reduce or minimize driver power losses. As discussed above, the base current I_{B} is a function of the maximum collector current that the device must carry (beta), so if a BJT required a 1 A base current from a 12V rail, this may result in a 12 W drive power loss, of which only 3 W would be due to the BJT (due to I_{B}*V_{BE}). As the driver circuitry 102 does not power the BJT 104 through a resistor, the drive power loss can be reduced. In addition, as the driver circuitry 102 may reduce the required steady state base current I_{B}, the driver circuitry 102 may further reduce the drive power loss during the conduction period of the BJT 104. To do this, the driver circuitry 102 may be configured to deliver additional peak currents at turn-on and turn-off to charge and discharge the C_{BE} and C_{BC} capacitances of the BJT 104. In order to achieve the benefits of extremely fast switching speeds of the BJT 104, peak currents should be in the range of 2 to 4 times the value of the base current I_{B}.

The driver circuitry 102 may be configured to mitigate the negative feedback effect of the source inductance. For example, the turn-on and turn-off peak currents must be sourced from a suitable voltage level (e.g, +10V or higher at turn-on and −10V or lower at turn-off). The driver circuitry 102 may be configured to provide the positive and high voltage initial peak current during turn-on of the BJT 104 and the steady state base current efficiently. For example, the driver circuitry 102 may be configured to provide close to a minimum voltage calculated using the following equation, VMIN=VBE+IB*RDRV, where IB*RDRV is the voltage drop across the driver circuit's 102 output impedance. The driver circuitry 102 may also be configured to achieve the desired turn-off current amplitude flowing out of the base terminal b of the BJT 104.

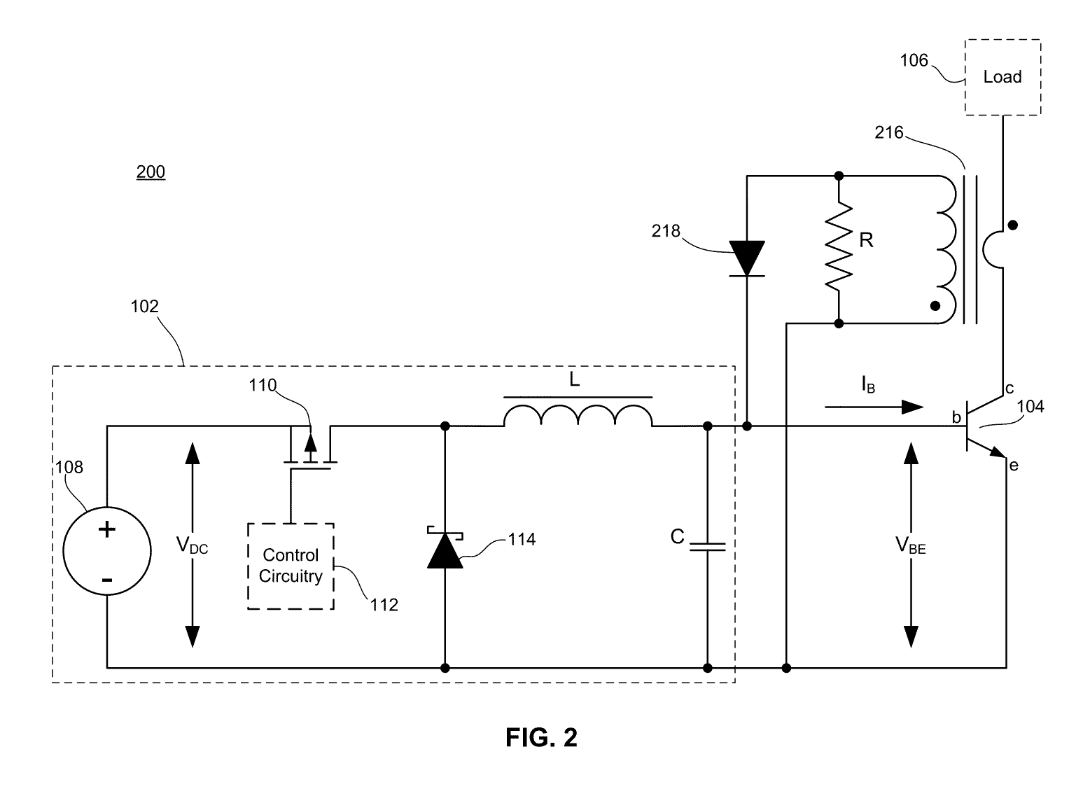

Turning to FIG. 2, another example embodiment of a system 200 for driving a transistor is illustrated. As shown, the system 200 includes the driver circuitry 102 and BJT 104 of FIG. 1. The system 200 further includes a current transformer 216 and a diode 218 coupled to the driver circuitry 102, BJT 104 and load 106 to provide a proportional base drive configuration. The system 200 may be configured to further improve the efficiency of the driver circuitry 102. For example, the current limit of the driver circuitry 102 may be set to a low value in order to provide just enough drive current to get the flow of the collector current started.

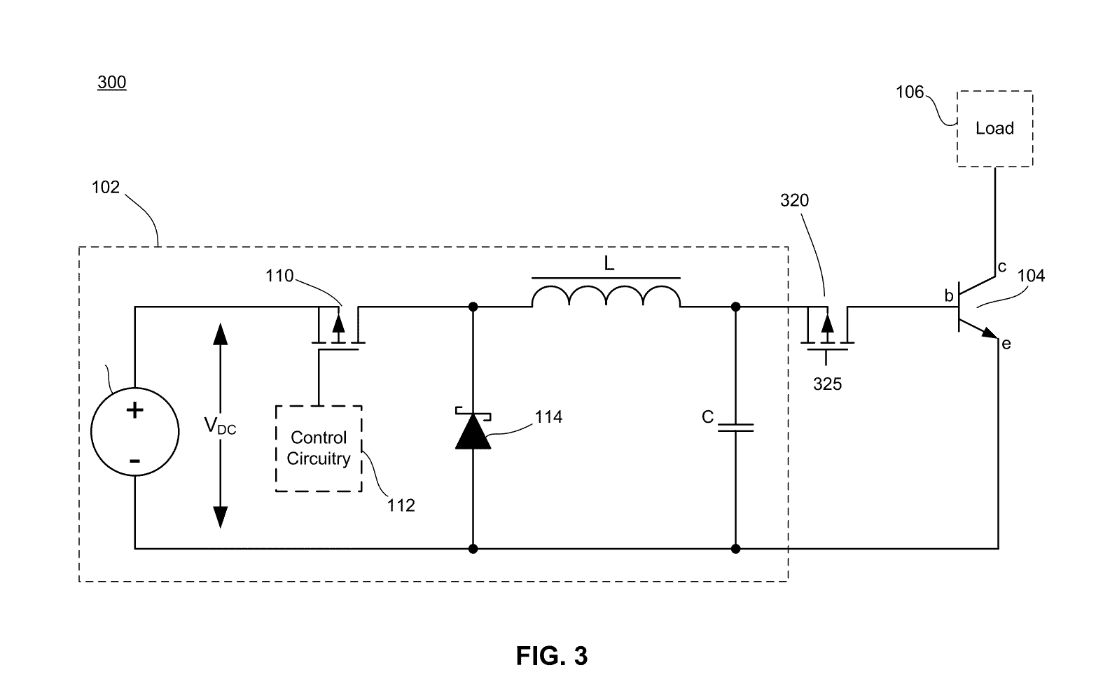

FIG. 3 illustrates a system 300 for driving a transistor according to some example embodiments. The system 300 illustrated in FIG. 3 is similar to the system 100 illustrated in FIG. 1, with the addition of a controlled switch 320 controlled by a signal 325. According to some example embodiments, the output of the driver circuitry 102 and the base terminal b of the BJT 104 may be separated by the controlled switch 320. The controlled switch 320 may allow the output capacitor C to charge to a higher voltage during the off-state of the BJT 104, whereby the driver circuitry 102 may idle at that higher voltage (for example, around 12V). At turn on of the BJT 104, the higher voltage stored in the output capacitor C may be discharged into the base terminal b of the BJT 104 to provide the initial high peak current generally required for fast switching action.

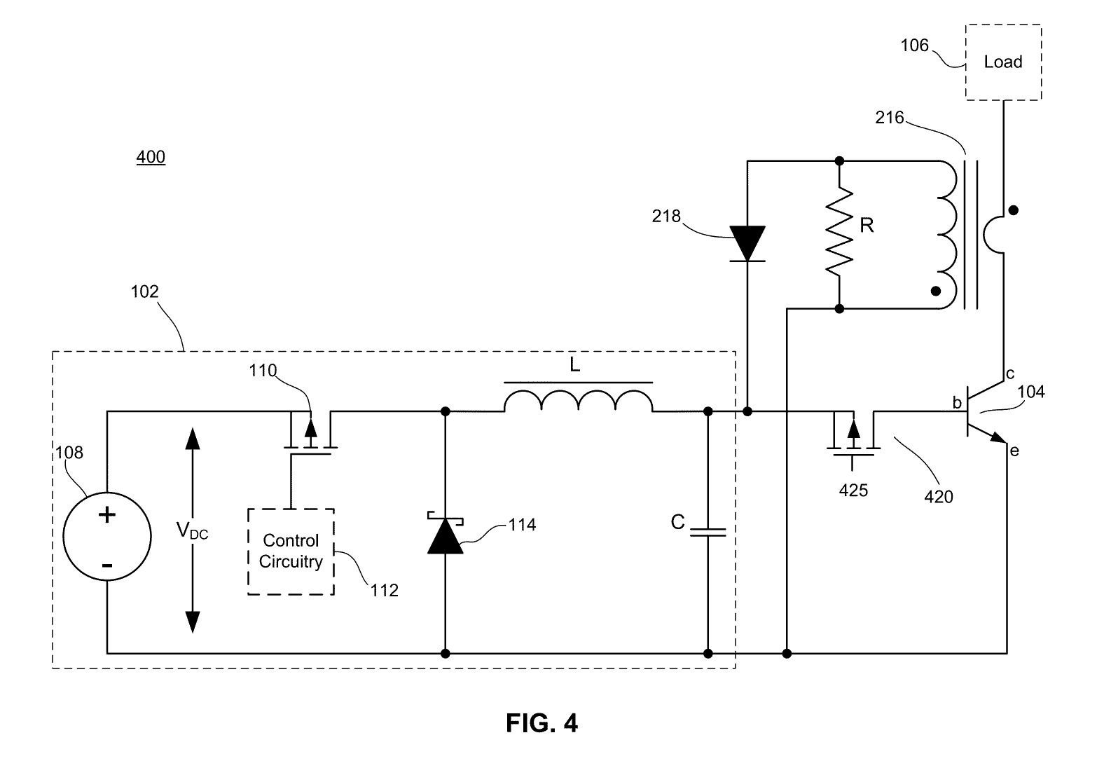

FIG. 4 illustrates a system 400 for driving a transistor according to some example embodiments. The system 400 illustrated in FIG. 4 is similar to the system 200 illustrated in FIG. 2, with the addition of a controlled switch 420 controlled by a signal 425. According to some example embodiments, the output of the driver circuitry 102 and the base terminal b of the BJT 104 may be separated by the controlled switch 420. The controlled switch 420 may allow the output capacitor C to charge to a higher voltage during the off-state of the BJT 104, whereby the driver circuitry 102 may idle at that higher voltage (for example, around 12V). At turn on of the BJT 104, the higher voltage stored in the output capacitor C may be discharged into the base terminal b of the BJT 104 to provide the initial high peak current generally required for fast switching action.

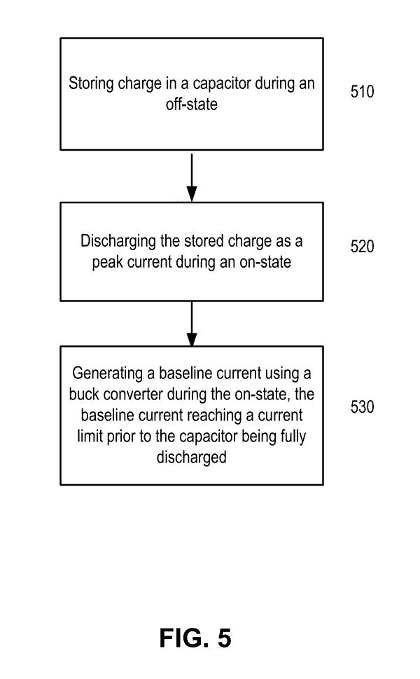

FIG. 5 illustrates a flowchart of operations according to some example embodiments. At step 510, charge may be stored in a capacitor during an off-state of the BJT 104. At step 520, the stored charge may be discharged as a peak current during an on-state of the BJT 104. At step 530, a baseline current may be generated using a buck converter during the on-state of the BJT 104, the baseline current reaching a current limit prior to the capacitor being fully discharged. Thus, the output current may be continuous between the peak current provided by the capacitor and the baseline current generated by the buck converter.

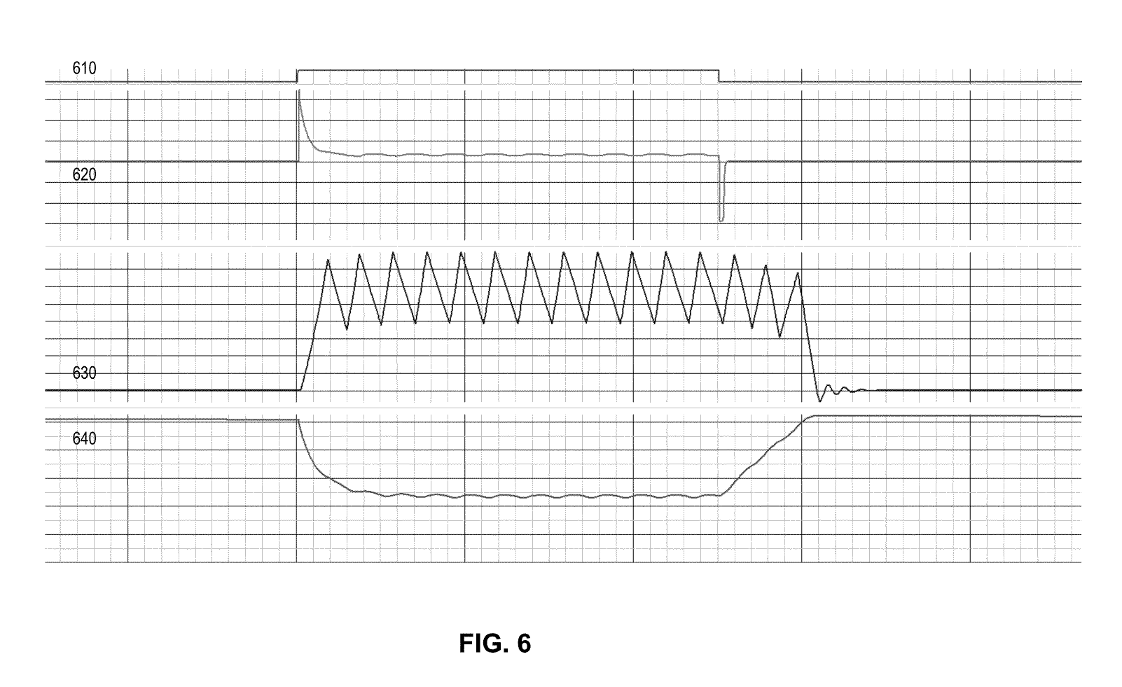

FIG. 6 illustrates a waveform diagram according to some example embodiments. Signal 610 is a control signal commanding the BJT 104 on or off, with a digital high signal corresponding to the BJT 104 being in an on-state. Signal 620 is an example of base current of the BJT 104. The initial peak current shown in signal 620 is caused by the output capacitor C discharging into the BJT 104. Signal 630 is an example of buck inductor current in the driver circuitry 102, and would be filtered by the output capacitor C to be the base current during the on-time of the BJT 104. Finally, signal 640 is an example of the buck output voltage.

Certain example embodiments described herein may be implemented in a system that includes one or more machine-readable storage mediums having stored thereon, individually or in combination, instructions that when executed by one or more processors perform the methods and/or operations described herein. The processor may include, for example, a system CPU (e.g., core processor) and/or programmable circuitry. Thus, it is intended that operations according to the methods described herein may be distributed across a plurality of physical devices, such as processing structures at several different physical locations.

The storage medium may include any type of tangible medium, for example, any type of disk including floppy disks, optical disks, compact disk read-only memories (CD-ROMs), compact disk rewritables (CD-RWs), digital versatile disks (DVDs) and magneto-optical disks, semiconductor devices such as read-only memories (ROMs), random access memories (RAMs) such as dynamic and static RAMs, erasable programmable read-only memories (EPROMs), electrically erasable programmable read-only memories (EEPROMs), flash memories, magnetic or optical cards, or any type of media suitable for storing electronic instructions.

As described herein, various example embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

“Circuitry” or “circuit”, as used in any embodiment herein, may include, for example, singly or in any combination, hardwired circuitry, programmable circuitry, state machine circuitry, firmware that stores instructions executed by programmable circuitry and/or circuitry available in a larger system, for example, discrete elements that may be included as part of an integrated circuit. In addition, any of the switch devices described herein may include any type of known or after-developed switch circuitry such as, for example, MOS transistors, BJT, SiC, etc.

Reference throughout this specification to “one example embodiment” or “an example embodiment” means that a particular feature, structure, or characteristic described in connection with the example embodiment is included in at least one example embodiment. Thus, appearances of the phrases “in one example embodiment” or “in an example embodiment” in various places throughout this specification are not necessarily all referring to the same example embodiment. Furthermore, the particular features, structures, or characteristics may be combined in any suitable manner in one or more example embodiments.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and example embodiments have been described herein. The features, aspects, and example embodiments are susceptible to combination with one another as well as to variation and modification, as will be understood by those having skill in the art. The present disclosure should, therefore, be considered to encompass such combinations, variations, and modifications.

What is claimed is:

1. Driver circuitry for driving a semiconductor device, the driver circuitry comprising:
a buck converter configured to generate a baseline current; and
a capacitor coupled between an output of the buck converter and ground, the capacitor configured to store charge during an off-state of the buck converter and to discharge the stored charge as a peak current during an on-state of the buck converter,
wherein the baseline current reaches a current limit prior to the capacitor being fully discharged, and an output current at an output of the driver circuitry is based on, at least in part, the baseline current and the peak current.

2. The driver circuitry of claim 1, wherein the semiconductor device is a bipolar junction transistor, and wherein the driver circuitry is configured to output the output current to a base terminal of the bipolar junction transistor.

3. The driver circuitry of claim 2, wherein the bipolar junction transistor is a Silicon Carbide device.

4. The driver circuitry of claim 1, further comprising:
a controlled switch coupled between the output of the buck converter and the output of the driver circuitry, the controlled switch configured to conduct during the on-state of the buck converter,
wherein the capacitor is configured to charge to a higher voltage while the controlled switch is not conducting than while the controlled switch is conducting.

5. The driver circuitry of claim 4, wherein the capacitor is configured to discharge the higher voltage into a base terminal of a bipolar junction transistor in the semiconductor device if the controlled switch begins to conduct.

6. The driver circuitry of claim 1, wherein the peak current is greater than at least twice the current limit of the baseline current.

7. The driver circuitry of claim 1, wherein the buck converter comprises:
an inductor coupled between an input voltage source and the output of the buck converter; and
a first switch coupled between the voltage source and the inductor.

8. The driver circuitry of claim 7, wherein the buck converter further comprises:
control circuitry configured to control the first switch to conduct in order to increase the baseline current and to control the first switch to not conduct to decrease the baseline current; and
a diode having a first end coupled to ground and a second end coupled between the inductor and the first switch, the diode configured to provide a path for inductor current during an off-state of the control circuitry.

9. The driver circuitry of claim 1, further comprising:
a transformer configured to generate a transformer current based on an external current,
wherein the output current at the output of the driver circuitry is based on, at least in part, the transformer current.

10. The driver circuitry of claim 9, further comprising:
a diode having a first end coupled to the output of the buck converter; and
a resistor coupled between a second end of the diode and ground,
wherein the current transformer is in parallel with the resistor.

11. The driver circuitry of claim 9, wherein the current limit of the baseline current is approximately equal to a minimum current required for operation of a bipolar junction transistor in the semiconductor device.

12. The driver circuitry of claim 11, wherein the current transformer is configured to increase the transformer current based on the external current.

13. A system, the system comprising:
a buck converter configured to generate a baseline current; and
a capacitor coupled between an output of the buck converter and ground, the capacitor configured to store charge during an off-state of the buck converter and to discharge the stored charge as a peak current during an on-state of the buck converter, wherein
the baseline current reaches a current limit prior to the capacitor being fully discharged,
an output current is based on, at least in part, the baseline current and the peak current, and
the peak current is greater than at least twice the current limit of the baseline current.

14. The system of claim 13, further comprising:
a bipolar junction transistor including Silicon Carbide, a base of the bipolar junction transistor configured to receive the output current.

15. The system of claim 13, further comprising:
a controlled switch coupled to the output of the buck converter, the controlled switch configured to conduct during the on-state of the buck converter,
wherein the capacitor is configured to charge to a higher voltage while the controlled switch is not conducting than while the controlled switch is conducting.

16. The system of claim 15, wherein the capacitor is configured to discharge the higher voltage into a base terminal of a bipolar junction transistor if the controlled switch begins to conduct.

17. The system of claim 14, further comprising:
a current transformer configured to generate a transformer current based on an external current,
wherein the output current is a sum of the baseline current, the peak current and the transformer current.

18. A method of generating an output current, the method comprising:
storing charge in a capacitor during an off-state of a buck converter;
discharging the stored charge as a peak current during an on-state of the buck converter; and
generating a baseline current using a buck converter during the on-state of the buck converter,
wherein
the baseline current reaches a current limit prior to the capacitor being fully discharged,
the output current is a sum of the baseline current and the peak current, and
the peak current is greater than twice the current limit of the baseline current.

19. The method of claim 18, further comprising:
driving a bipolar junction transistor including Silicon Carbide with the output current.

20. The method of claim 19, further comprising:
generating a transformer current based on a current at a collector of the bipolar junction transistor, wherein the output current is a sum of the baseline current, the peak current and the transformer current.
